(19) United States
(12) Patent Application Publication
(10) Pub. No.: US 2011/0147058 A1
(43) Pub. Date: Jun. 23, 2011

(54) ELECTRONIC DEVICE AND METHOD OF MANUFACTURING ELECTRONIC DEVICE

(75) Inventors: Masaya KAWANO, Kanagawa (JP); Koji SOEJIMA, Kanagawa (JP)

(73) Assignee: RENESAS ELECTRONICS CORPORATION, Kanagawa (JP)

(21) Appl. No.: 12/973,162

(22) Filed: Dec. 20, 2010

(30) Foreign Application Priority Data
Dec. 21, 2009 (JP) 2009-289822

(51) Int. Cl. H05K 1/09; H05K 1/18; H05K 3/10

(52) U.S. Cl. 174/257; 174/260; 29/846

(57) ABSTRACT

A multilayer wiring substrate has a configuration in which a first wiring layer including a plurality of first conductive members formed in a first insulating film, and formed to be exposed at a second surface side, and a second wiring layer including a plurality of second conductive members formed in a second insulating film which is formed on a first surface side on the side opposite to the second surface are laminated. The plurality of second conductive members is respectively connected directly to any of the plurality of first conductive members or connected through a different conductive material. The plurality of first conductive members is connected directly to any of the plurality of second conductive members or connected through a different conductive material, but includes dummy conductive members which do not form current pathways connecting with connected second conductive member.

This application is based on Japanese patent application No. 2009-289822, the content of which is incorporated hereinto by reference.

### BACKGROUND

1. Technical Field

The present invention relates to an electronic device and a method of manufacturing the electronic device.

2. Related Art

Japanese Unexamined Patent Publication No. 2000-299404 discloses a configuration in which a wiring pattern is formed on both surfaces or a single side surface of a core substrate, and in a multilayer wiring substrate where the wiring pattern is electrically connected to a conductor portion formed by passing through the core substrate, the core substrate includes a conductor portion composed of a via column formed by plating and a conductor core portion, and an insulator portion electrically insulating the via column from the conductor core portion. The via column and the conductor core portion are formed by formation of a conductor layer by electroless copper plating or sputtering and the like, followed by formation of a resist pattern, and performing electrolytic copper plating using the conductor layer as a feed layer. The multilayer wiring substrate is obtained by forming the wiring pattern on the core substrate, and then removing the conductor substrate.

Japanese Unexamined Patent Publication No. 2001-308532 discloses a method of manufacturing a printed circuit board including a step of hole drilling from the resin layer side of a single-sided copper-clad laminated substrate to the copper foil surface, a step of filling a hole formed in the resin layer by electrolytic plating using the copper foil as a feed layer, a step of planarizing a filling surface of the hole, a step of roughening the surface of the resin layer, a step of forming a conductive pattern on the resin layer, a step of forming a built-up resin layer on the resin layer in which the conductive pattern is formed, a step of hole-drilling the built-up resin layer up to the surface of the filling surface, and a step of filling the hole formed in the built-up resin layer by electrolytic plating using the copper foil as the feed layer.

### SUMMARY

However, in the technique disclosed in Japanese Unexamined Patent Publication No. 2000-299404, there has been a problem that whenever electrolytic plating is performed, it is necessary to form the film serving as the electrolytic plating feed layer by sputtering or electroless plating, which results in high manufacturing costs.

In one embodiment, there is provided an electronic device comprising: a multilayer wiring substrate having a first surface and a second surface which oppose to the first surface, a first insulating film which forms the second surface side of the multilayer wiring substrate, a plurality of first conductive members formed in the first insulating film to be exposed at the second surface side of the multilayer wiring substrate, and which composes a first wiring layer with the first insulating film, a second insulating film which forms the first surface side of the multilayer wiring substrate, a plurality of second conductive members formed in the second insulating film, and which composes a second wiring layer with the second insulating film, and a first electronic component mounted at the first surface of the multilayer wiring substrate and electrically connected to any of the plurality of second conductive members, wherein the plurality of second conductive members is respectively connected directly to any of the plurality of first conductive members or connected through a different conductive material, and the plurality of first conductive members includes a dummy conductive member, and the dummy conductive member is connected directly to any of the plurality of second conductive members or connected through a different conductive material, but do not form current pathways connecting with the connected second conductive member.

In another embodiment, there is provided a method of manufacturing an electronic device, including: forming a third insulating film over a plurality of third conductive members which is formed over a feed layer, and is respectively electrically connected to the feed layer, forming a plurality of openings, respectively, that exposes at least one of the plurality of third conductive members to the third insulating film, forming a plurality of fourth conductive members within the plurality of openings in the third insulating film by an electrolytic plating method of feeding from the feed layer, to form a third wiring layer including the plurality of fourth conductive members and the third insulating film, mounting a fourth electronic component over the third wiring layer, and electrically connecting any of the plurality of fourth conductive members to the fourth electronic component, and removing the feed layer, wherein when the plurality of fourth conductive members is formed, a dummy conductive member provided in order to feed from the feed layer is provided between the plurality of fourth conductive members and the feed layer.

According to such a configuration, it is possible to form the plurality of second conductive members or the plurality of fourth conductive members by the electrolytic plating method of feeding from the feed layer by providing the dummy conductive member. Thereby, whenever the electrolytic plating is performed, it is not necessary to form a film serving as the electrolytic plating feed layer by sputtering or electroless plating. Therefore, it is possible to form the plurality of second conductive members and the plurality of fourth conductive members through a simple procedure.

Meanwhile, arbitrary combinations of the above-mentioned components, and ones obtained by conversion of the expression of the invention among methods, devices and the like are also effective as an aspect of the invention.

According to the invention, it is possible to form the conductive members of the multilayer wiring substrate in a simple procedure.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating an example of a configuration of an electronic device according to an embodiment of the invention.

FIG. 2 is a cross-sectional view for explaining the connection status of each via and each wiring pattern of the electronic device shown in FIG. 2.

FIGS. 3A and 3B are process cross-sectional views illustrating an example of a manufacturing procedure of the electronic device according to the embodiment of the invention.

FIGS. 4A and 4B are process cross-sectional views illustrating an example of the manufacturing procedure of the electronic device according to the embodiment of the invention.

FIGS. 5A and 5B are process cross-sectional views illustrating an example of the manufacturing procedure of the electronic device according to the embodiment of the invention.

FIGS. 6A and 6B are process cross-sectional views illustrating an example of the manufacturing procedure of the electronic device according to the embodiment of the invention.

FIGS. 7A and 7B are process cross-sectional views illustrating an example of the manufacturing procedure of the electronic device according to the embodiment of the invention.

FIGS. 8A and 8B are process cross-sectional views illustrating an example of the manufacturing procedure of the electronic device according to the embodiment of the invention.

FIG. 9 is a process cross-sectional view illustrating an example of the manufacturing procedure of the electronic device according to the embodiment of the invention.

FIG. 10 is a process cross-sectional view illustrating an example of the manufacturing procedure of the electronic device according to the embodiment of the invention.

FIG. 11 is a process cross-sectional view illustrating an example of the manufacturing procedure of the electronic device according to the embodiment of the invention.

FIG. 12 is a cross-sectional view illustrating another example of the configuration of the electronic device according to the embodiment of the invention.

FIG. 13 is a cross-sectional view illustrating another example of the configuration of the electronic device according to the embodiment of the invention.

FIG. 14 is a cross-sectional view illustrating another example of the configuration of the electronic device according to the embodiment of the invention.

FIG. 15 is a cross-sectional view illustrating another example of the configuration of the electronic device according to the embodiment of the invention.

FIGS. 16A and 16B are process cross-sectional views illustrating another example of the manufacturing procedure of the electronic device according to the embodiment of the invention.

FIGS. 17A and 17B are process cross-sectional views illustrating another example of the manufacturing procedure of the electronic device according to the embodiment of the invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiment of the invention will be described with reference to the accompanying drawings. In all the drawings, like elements are referenced by like reference numerals and descriptions thereof will not be repeated.

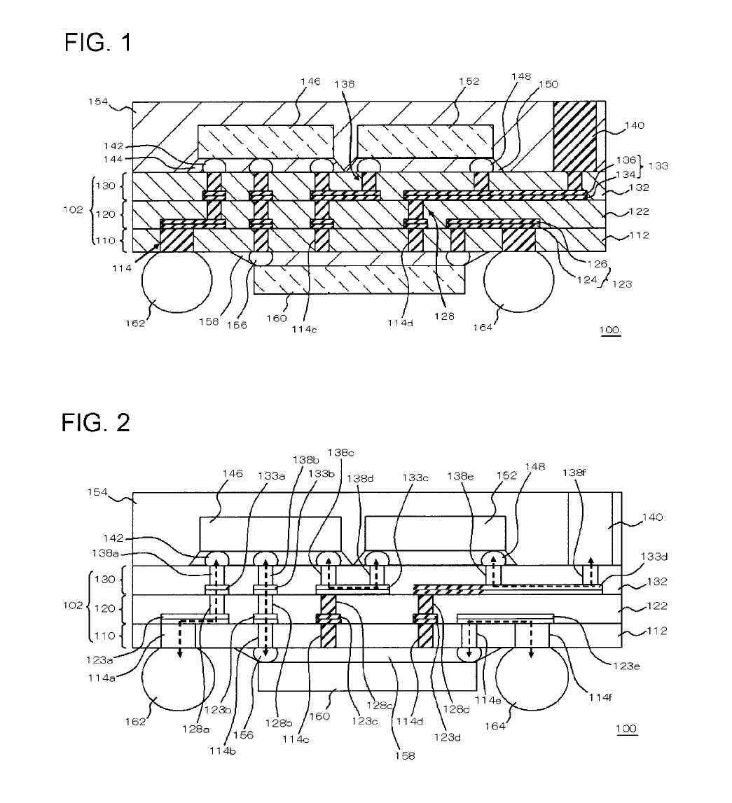

FIG. 1 is cross-sectional view illustrating a configuration of an electronic device 100 according to the embodiment.

The electronic device 100 includes a multilayer wiring substrate 102, an electronic component 146 (first electronic component and fourth electronic component) and an electronic component 152 (second electronic component) mounted on the first surface of the multilayer wiring substrate 102, and an electronic component 160 (third electronic component) mounted on the second surface of the multilayer wiring substrate 102.

The electronic component 146, the electronic component 152, and the electronic component 160 can be, for example, semiconductor chips such as an LSI or passive components such as a resistor, and the like. In the embodiment, an example will be described in which the electronic component 146, the electronic component 152, and the electronic component 160 are semiconductor chips, respectively. Moreover, in the embodiment, the electronic component 146, the electronic component 152, and the electronic component 160 are respectively mounted on the multilayer wiring substrate 102 through a flip-chip connection. The electronic device 100 can be a SiP or a PoP, and the like.

The multilayer wiring substrate 102 includes a wiring layer 110 (first wiring layer and fourth wiring layer), a wiring layer 120, and a wiring layer 130 (second wiring layer and third wiring layer) which are laminated in this order from the second surface side (lower side in the drawing). The wiring layer 130 is formed on the first surface side of the multilayer wiring substrate 102.

The wiring layer 110 includes an insulating film 112 (first insulating film and fourth insulating film), and a plurality of vias 114 (including vias 114c and 114d) (first conductive member and fifth conductive member) formed in the insulating film 112. The plurality of vias 114 is exposed in the second surface of the multilayer wiring substrate 102. The wiring layer 120 includes an insulating film 122, and a wiring pattern 123 and a plurality of vias 128 formed in the insulating film 122. The wiring pattern 123 is constituted by a sputtered wiring film 124 and a plated wiring film 126. The wiring layer 130 includes an insulating film 132 (second insulating film and third insulating film), a wiring pattern 133 (third conductive member) and a plurality of vias 138 (second conductive member and fourth conductive member) formed in the insulating film 132. The wiring pattern 133 includes a sputtered wiring film 134 and a plated wiring film 136.

The insulating film 112, the insulating film 122, and the insulating film 132 can be formed of, for example, a polyimide film. Further, in the embodiment, the insulating film 112 and the insulating film 132 can be formed of a solder resist layer.

Each of the wiring patterns and the vias can be formed of, for example, copper or nickel and the like. Further, in the wiring layer 130, the vias 138 connected to the electronic component such as the electronic component 146 and a different member such as a terminal can be configured so that a solder material such as, for example, an alloy of tin and silver is provided to the side connected to the different member. For example, each of the vias 138 can be configured to have a laminated structure of a copper film and an alloy film of tin and silver, or a laminated structure of a nickel film and an alloy film of tin and silver, and the like, from the lower side in the drawing. In addition, each of the vias 138 can be configured so that gold is further formed on the surface thereof.

The electronic component 146 is electrically connected to any of a plurality of vias 138 of the wiring layer 130 through a bump 142. An underfill 144 is provided between the electronic component 146 and the multilayer wiring substrate 102 so as to bury the bump 142. The electronic component 146 is bonded to the multilayer wiring substrate 102 by the underfill 144.

In addition, the electronic component 152 is similarly electrically connected to any of a plurality of vias 138 of the wiring layer 130 through a bump 148. An underfill 150 is provided between the electronic component 152 and the multilayer wiring substrate 102 so as to bury the bump 148. The electronic component 152 is bonded to the multilayer wiring substrate 102 by the underfill 150. The bump 142 and the bump 148 can be formed of a solder material.

A terminal 140 is a terminal to be connected to the back side of the electronic component 152. In the first surface of the multilayer wiring substrate 102, the electronic component 146, the electronic component 152 and the terminal 140 are sealed with a sealing resin 154. The sealing resin 154 can be formed of, for example, an epoxy resin. In the embodiment, since the electronic component 146 and the electronic component 152 are sealed with the sealing resin 154, the underfill 144 and the underfill 150 may not be provided.

A solder ball 162 and a solder ball 164 connected to any of a plurality of vias 114 of the wiring layer 110 respectively are provided on the second surface of the multilayer wiring substrate 102. The electronic component 160 is connected to any of the plurality of vias 114 of the wiring layer 110 through a bump 156. An underfill 158 is provided between the electronic component 160 and the multilayer wiring substrate 102 so as to bury the bump 156. The electronic component 160 is bonded to the multilayer wiring substrate 102 by the underfill 158.

In the embodiment, in the multilayer wiring substrate 102, a plurality of vias 138 formed in the wiring layer 130 is respectively connected to any of the plurality of vias 114 formed in the wiring layer 110 through another conductive material. In addition, the plurality of vias 114 formed in the wiring layer 110 is connected to any of the plurality of vias 138 formed in the wiring layer 130 through another conductive material, but includes dummy vias (dummy conductive members) which do not have current pathways between the connected vias 138. Here, the dummy conductive members can be configured not to be connected to other wiring s or silicon surfaces such as the electronic components.

FIG. 2 is a cross-sectional view illustrating the same configuration as the electronic device 100 shown in FIG. 1.

Herein, for the purpose of description, each of the components is not hatched except a portion thereof. In addition, the components are distinguished from each other by assigning reference numbers to the vias and the wiring patterns in each of the wiring layers. In addition, the locations which are electrically connected to each other and form current pathways there between are shown by arrows (dashed lines).

For example, a via 138a and a wiring pattern 133a of the wiring layer 130, a via 128a and a wiring pattern 123a of the wiring layer 120, and a via 114a of the wiring layer 110 form the current pathway for connecting the electronic component 146 and the solder ball 162 through the bump 142.

In addition, a via 138b and a wiring pattern 133b of the wiring layer 130, a via 128b and a wiring pattern 123b of the wiring layer 120, and a via 114b of the wiring layer 110 form the current pathway for connecting the electronic component 146 and the electronic component 160 through the bump 142 and the bump 156, respectively.

In addition, a via 138c, a wiring pattern 133c, and a via 138d of the wiring layer 130 form the current pathway for connecting the electronic component 146 and the electronic component 152 through the bump 142 and the bump 148, respectively.

In addition, a via 138e, a portion of a wiring pattern 133d, and a via 138f of the wiring layer 130 form the current pathway for connecting the electronic component 152 and the terminal 140 through the bump 148.

In addition, a via 114e of the wiring layer 110, a wiring pattern 123e of the wiring layer 120, and a via 114f form the current pathway for connecting the electronic component 160 and the solder ball 164 through the bump 156.

On the other hand, a via 128c and a wiring pattern 123c of the wiring layer 120 and a via 114c of the wiring layer 110, which are hatched in the drawing, do not form the current pathway connecting with the via 138c, the wiring pattern 133c, and the via 138d of the wiring layer 130. Similarly, the remaining portion of the wiring pattern 133d of the wiring layer 130, a via 128d and a wiring pattern 123d of the wiring layer 120, and the via 114d of the wiring layer 110, which are hatched in the drawing, do not form the current pathway connecting with the via 138e, a portion of the wiring pattern 133d, and the via 138f of the wiring layer 130. That is, these are dummy conductive members. Dummy conductive members (via 114c and via 114d) do not connect the bump 156, the bump 148, the bump 156, the solder ball 162, the solder ball 164 and the terminal 140 mutually.

Meanwhile, in the embodiment, the exposed surfaces of the dummy conductive members in the second surface of the multilayer wiring substrate 102 can be formed in contact with an insulating material. Thereby, it is possible to prevent short circuits and the like of the dummy conductive members in the second surface side of the multilayer wiring substrate 102. In the embodiment, as the insulating material, the underfill 158 can be used.

Further, in the embodiment, the dummy conductive members can be formed to be exposed within a region overlapping the electronic component 160 in the second surface of the multilayer wiring substrate 102. That is, in the embodiment, the via 114c and the via 114d which are the dummy conductive members exposed in the second surface of the multilayer wiring substrate 102 can be formed to be exposed within a region overlapping the electronic component 160. Here, the region overlapping the electronic component 160 can be a region in which the underfill 158 is formed. In the embodiment, the via 114c and the via 114d which are the dummy conductive members can be brought into contact with the underfill 158 at the exposed surfaces thereof.

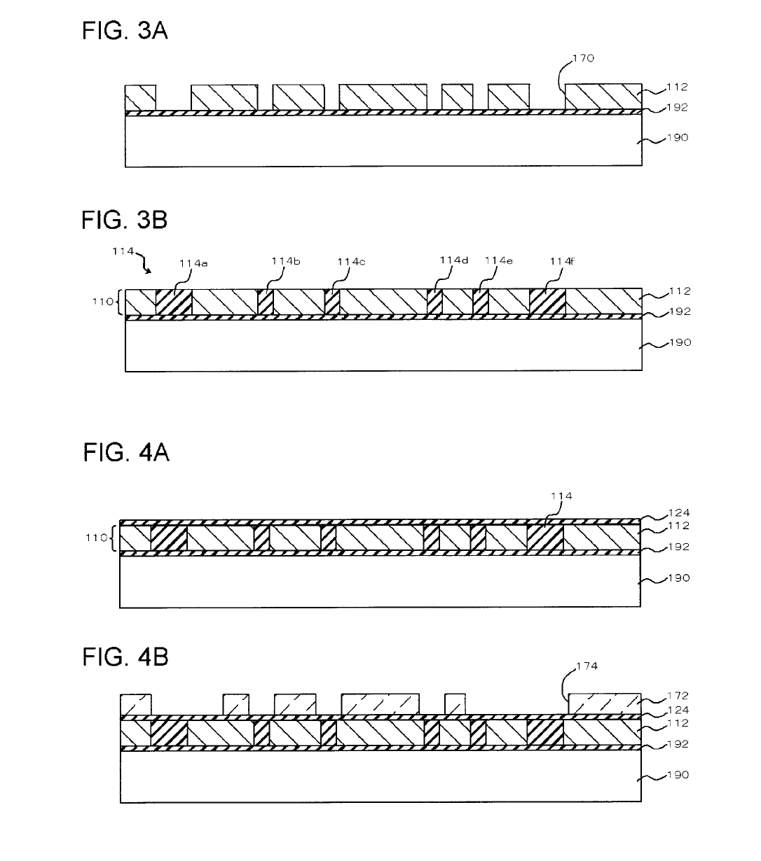

Next, a manufacturing procedure of the electronic device 100 in the embodiment will be described. FIGS. 3A to 11 are process cross-sectional views illustrating a manufacturing procedure of the electronic device 100 in the embodiment.

First, a feed layer 192 is formed on a support 190. The feed layer 192 can be formed of, for example, a copper film and the like. The support 190 can be formed of, for example, silicon and the like. The feed layer 192 can be formed by sputtering.

Subsequently, the insulating film 112 having an opening 170 is formed on the feed layer 192 (FIG. 3A).

Next, a plurality of vias 114 (via 114a, via 114b, via 114c, via 114d, via 114e, and via 114f) is formed by an electrolytic plating method of feeding from the feed layer 192. Thereby, the wiring layer 110 is formed (FIG. 3B).

Thereafter, the sputtered wiring film 124 is formed on the wiring layer 110 by sputtering (FIG. 4A). Subsequently, a resist film 172 having an opening 174 is formed on the sputtered wiring film 124 (FIG. 4B).

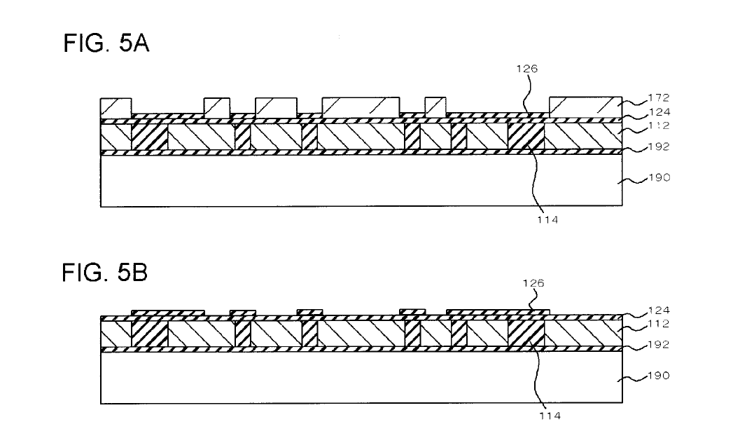

Subsequently, the plated wiring film 126 is formed by the electrolytic plating method of feeding from the sputtered wiring film 124 (FIG. 5A). Next, the resist film 172 is removed (FIG. 5B).

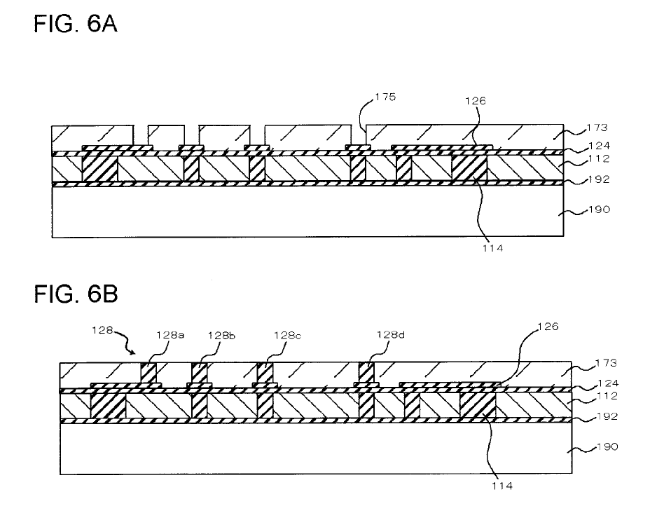

Thereafter, a resist film 173 having an opening 175 is formed on the sputtered wiring film 124 and the plated wiring film 126 (FIG. 6A). A plurality of vias 128 (via 128a, via 128b, via 128c, and via 128d) is formed by the electrolytic plating method of feeding from the sputtered wiring film 124 (FIG. 6B).

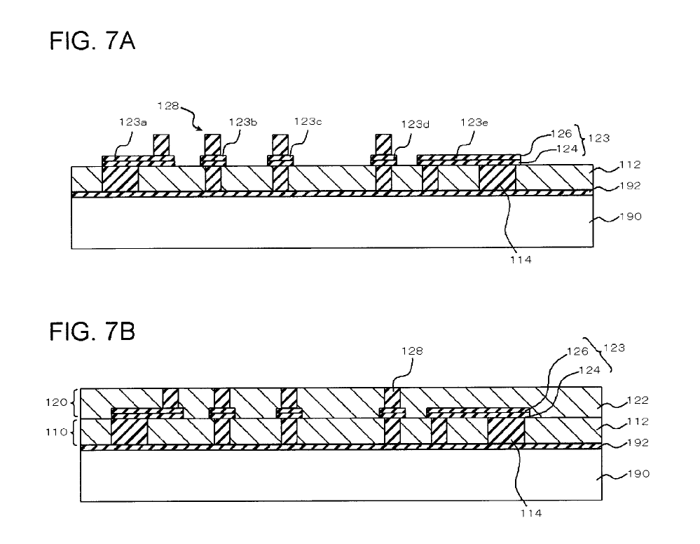

Next, the resist film 173 is removed, and the sputtered wiring film 124 is etched using the plated wiring film 126 as a mask. Thereby, the wiring patterns 123 (wiring pattern 123a, wiring pattern 123b, wiring pattern 123c, wiring pattern 123d, and wiring pattern 123e) are formed (FIG. 7A).

Subsequently, the insulating film 122 is formed on the entire surface of a plurality of wiring patterns 123 and a plurality of vias 128 so as to cover them. Next, the surface of the insulating film 122 is cut, and then the surface thereof is planarized and the plurality of vias 128 is exposed. Thereby, the wiring layer 120 is formed (FIG. 7B).

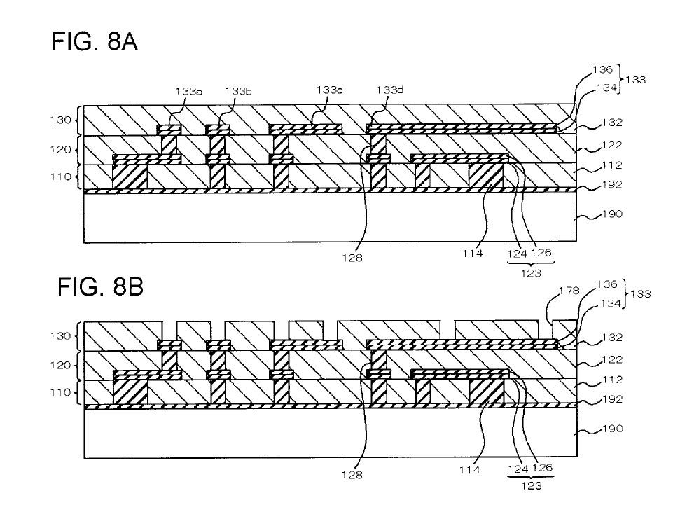

Next, similarly to the wiring pattern 123 of the wiring layer 120, the wiring patterns 133 (wiring pattern 133a, wiring pattern 133b, wiring pattern 133c, and wiring pattern 133d) are formed on the wiring layer 120, and then the insulating film 132 is formed on the wiring patterns 133 (FIG. 8A).

After this, a plurality of openings 178 is formed on the insulating film 132 (FIG. 8B). The openings 178 can be formed by forming a resist film (not shown) having openings on the insulating film 132, and etching the insulating film 132 using the resist film as a mask.

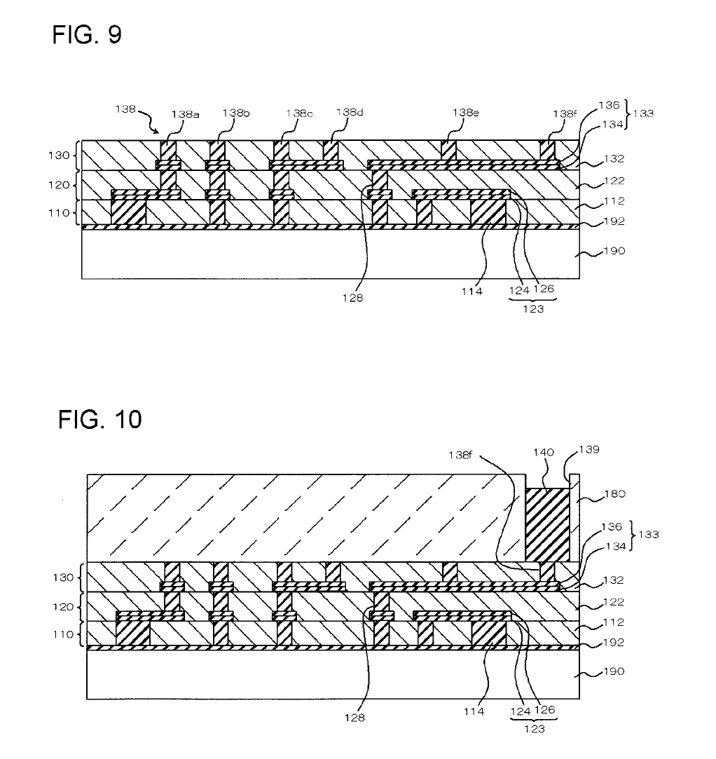

Subsequently, a plurality of vias 138 (via 138a, via 138b, via 138c, via 138d, via 138e, and via 138f) is formed within the openings 178 by the electrolytic plating method of feeding from the feed layer 192. In the embodiment, a plurality of theses vias 138 can be formed to have, for example, a laminated structure of a copper film and an alloy film of tin and silver, or a laminated structure of a nickel film and an alloy film of tin and silver. In addition, a gold plated film can be formed on the surfaces of a plurality of vias 138. Thereby, the wiring layer 130 is formed (FIG. 9).

Next, a resist film 180 having an opening 139 which opens on the via 138f is formed on the entire surface of the wiring layer 130. Thereafter, the terminal 140 is formed within the opening 139 by the electrolytic plating method of feeding from the feed layer 192.

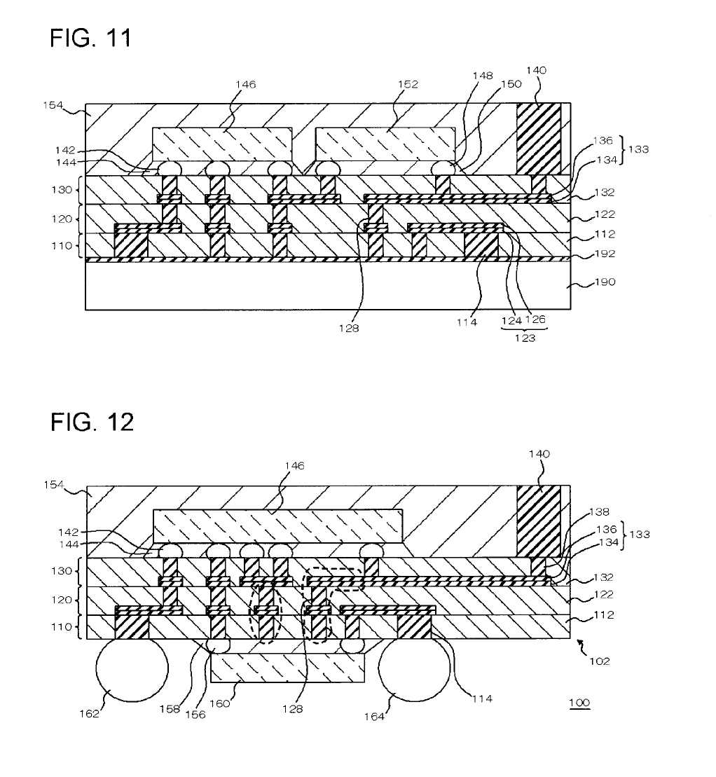

After this, the resist film 180 is removed, and the electronic component 146 and the electronic component 152 are mounted on the first surface of the multilayer wiring substrate 102 by the following procedure. First, the electronic component 146 and the electronic component 152 are mounted on the multilayer wiring substrate 102 through the bump 142 and the bump 148 such as a solder. Next, the underfill 144 and the underfill 150 are respectively provided between the electronic component 146 and electronic component 152, and the multilayer wiring substrate 102. Thereby, the bump 142 and the bump 148 are respectively covered with the underfill 144 and the underfill 150. Subsequently, the electronic component 146, the electronic component 152, and the terminal 140 are sealed with the sealing resin 154 (FIG. 11).

After this, the support 190 is removed by, for example, grinding and the like. Next, the feed layer 192 is removed by etching and the like, and a plurality of vias 114 is exposed to the second surface side of the multilayer wiring substrate 102. After this, the electronic component 160 is mounted on the back side of the multilayer wiring substrate 102. First, the electronic component 160 is mounted on the multilayer wiring substrate 102 through the bump 156 such as a solder. Next, the underfill 158 is provided between the electronic component 160 and the multilayer wiring substrate 102. Thereby, the bump 156 is covered with the underfill 158. In addition, the solder ball 162 and the solder ball 164 are mounted. Thereby, the electronic device 100 having a configuration shown in FIG. 1 is obtained.

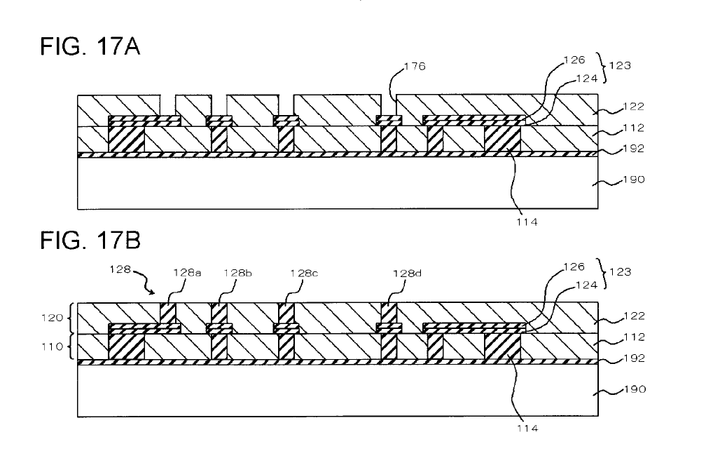

In addition, using another example, the wiring layer 120 can also be formed by the same procedure as that in the wiring layer 130. Hereinafter, a description will be made with reference to FIGS. 16A and 16B and FIGS. 17A and 17B. FIGS. 16A and 16B and FIGS. 17A and 17B are process cross-sectional views illustrating another example of a manufacturing procedure of the electronic device 100 in the embodiment.

Subsequently to the procedure described with reference to FIGS. 5A and 5B, the sputtered wiring film 124 is etched using the plated wiring film 126 as a mask. Thereby, the wiring patterns 123 (wiring pattern 123a, wiring pattern 123b, wiring pattern 123c, wiring pattern 123d, and wiring pattern 123e) are formed (FIG. 16A).

Subsequently, the insulating film 122 is formed on the entire surface of the wiring layer 110 so as to cover the wiring patterns 123 (FIG. 16B). After this, an opening 176 is formed in the insulating film 122 (FIG. 17A). The opening 176 can be formed by forming a resist film (not shown) having an opening on the insulating film 122, and etching the insulating film 122 using the resist film as a mask.

Subsequently, a plurality of vias 128 (via 128a, via 128b, via 128c, and via 128d) is formed within the opening 176 by the electrolytic plating method of feeding from the feed layer 192. Thereby, the wiring layer 120 is formed (FIG. 17B). After this, the electronic device 100 shown in FIG. 1 can be obtained by the same procedure as that described with reference to FIGS. 8A to 11.

As described above, in the embodiment, the vias 138 for performing the connection of the electronic component 146 and the electronic component 152 mounted on the first surface side of the multilayer wiring substrate 102, or the connection of the electronic component 152 and the terminal 140, which seems not to be connected to the feed layer on the support from the viewpoint of a circuit design, are also connected to the vias 114 of the wiring layer 110 in the second surface side of the multilayer wiring substrate 102 through a conductive material. Thereby, the following effect is obtained.

According to the manufacturing procedure of the electronic device 100 in the embodiment, the dummy conductive members are provided, and each of the vias 138 of the wiring layer 130 is connected to any of the vias 114 through the conductive materials such as the wiring patterns 123, the vias 128, and the wiring patterns 133. For this reason, each of the vias 138 can be formed by the electrolytic plating method of feeding from the power supply layer 192. Here, when feeding is not performed from the feed layer 192, it is necessary to newly form the feed layer for electrolytic plating by sputtering or electroless plating every time electrolytic plating is performed. However, according to the manufacturing procedure of the electronic device 100 in the embodiment, it is not necessary to newly form such a feed layer for electrolytic plating, and thus the vias 138 can be formed through a simple procedure.

In addition, according to the manufacturing procedure of the electronic device 100 in the embodiment, the insulating film 132 of the uppermost layer is formed before the vias 138 are formed. For this reason, it is possible to planarize the surface of the insulating film 132. Thereby, it is possible to planarize the surface of the wiring layer 130 on which the electronic component 146 or the electronic component 152 is mounted, to reduce an underfill void at the time of forming the underfill 144 or the underfill 150, and to obtain good electrical characteristics for the electronic device 100.

Further, in the embodiment, the dummy vias (vias 114) exposed to the second surface side of the multilayer wiring substrate 102 among the dummy conductive members are exposed to a region overlapping the electronic component 160. In addition, the dummy vias (vias 114) exposed to the second surface side of the multilayer wiring substrate 102 are buried by the underfill 158. Thereby, it is possible to prevent short circuits and the like of the dummy conductive members at the second surface side of the multilayer wiring substrate 102.

In addition, it is possible to form a heat-dissipating path between the electronic component 160 provided to the back side of the multilayer wiring substrate 102, and the electronic component 146 and the electronic component 152 provided to the surface side of the multilayer wiring substrate 102 by providing such dummy conductive members. Thereby, it is possible to improve heat-dissipating capability of the electronic device 100.

In addition, for example, with respect to the wiring layer 130 on the first surface side of the multilayer wiring substrate 102, it is considered that similarly to the formation procedure of the wiring layer 120 described with reference to FIG. 7B, when the vias 128 are formed to form the insulating film 122, and then the surface of the insulating film 122 is planarized, the surface of the wiring layer 130 can also be planarized. However, since the vias 138 in the uppermost surface of the multilayer wiring substrate 102 are connected to the semiconductor chips such as the electronic component 146, for example, gold and the like may be formed on the surface thereof in order to reduce the insulating film as mentioned above is performed, there may be a concern that gold formed on the surfaces of the vias 138 will be cut. However, in the embodiment, by using the electrolytic plating method of supplying power from the power supply layer 192, the vias 138 can be formed after the insulating film 132 is formed, and thus it is possible to planarize the surface of the wiring layer 130 without performing the planarizing process.

Next, another example of the electronic device 100 in the embodiment will be described.

The configuration of the electronic device 100 shown in FIG. 12 is different from that of the electronic device 100 shown in FIG. 1, in that it does not include the electronic component 152. Even in such a configuration, the wiring layer 130 is provided with, for example, the current pathway for connecting a plurality of bumps 142 connected to the electronic component 146, or the current pathway for connecting the electronic component 146 and the terminal 140. In addition, the wiring layer 110 and the wiring layer 120 are provided with the dummy conductive members connected to these current pathways. Here, the places surrounded by the dashed lines in the drawing correspond to the dummy conductive members which do not form the current pathways.

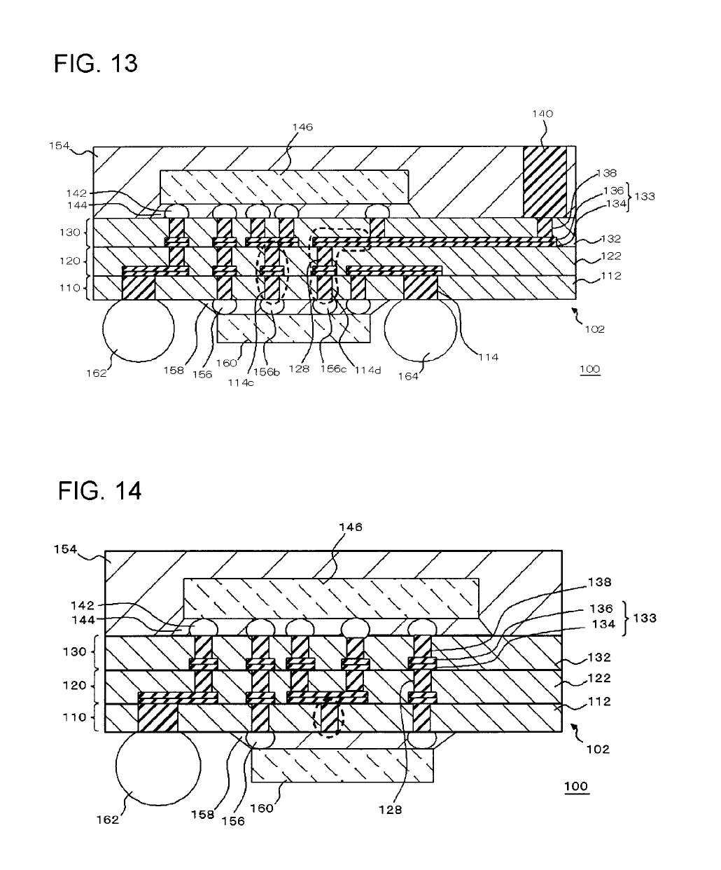

The configuration of the electronic device 100 shown in FIG. 13 is different from that of the electronic device 100 shown in FIG. 12, in that the bump 156b and the bump 156c, which are provided to be connected to the dummy conductive members (via 114c and via 114d) and are not electrically connected to a different member, are provided to the second surface of the multilayer wiring substrate 102. Even in this case, the bump 156b and the bump 156c can be configured to be provided to a region overlapping the electronic component 160, and to be buried by the underfill 158. Here, the bump 156b and the bump 156c are not electrically connected to the electronic component 160. That is, the bump 156b and the bump 156c do not work as the external terminal. Further, in the configuration of the electronic device 100 shown in FIG. 1, it is also possible to provide the bumps which are respectively connected to the vias 114c and via 114d, and are not electrically connected to the electronic component 160.

The electronic device 100 shown in FIG. 14 is different from the electronic device 100 shown in FIG. 12, in that it does not include the terminal 140, and that it does not include the dummy conductive members in the wiring layer 130 and the wiring layer 120. Herein, the place surrounded by the dashed line in the drawing corresponds to the dummy conductive member which does not form the current pathway. In this example, the dummy conductive member is provided only to the wiring layer 110.

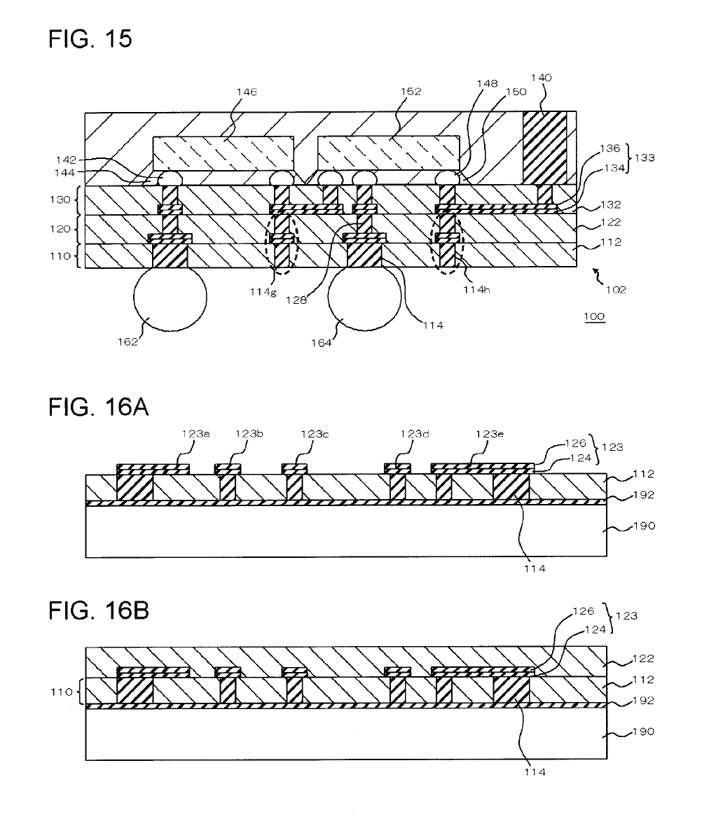

The electronic device 100 shown in FIG. 15 is different from the electronic device 100 shown in FIG. 1, in that it does not include the electronic component 160. Herein, the places surrounded by the dashed lines in the drawing correspond to the dummy conductive members which do not form the current pathway. Although not shown in the drawing, in such a configuration, the exposed surfaces of the dummy conductive members in the second surface of the multilayer wiring substrate 102 can be formed in contact with an insulating material. For example, it is possible to provide the insulating material to the exposed surfaces of the via 114g and the via 114h exposed to the second surface side of the multilayer wiring substrate 102.

As described above, although the embodiments of the invention have been set forth with reference to the drawings, they are merely illustrative of the invention, and various configurations other than those stated above can be adopted.

In the embodiments mentioned above, an example has been illustrated in which the electronic components such as the electronic component 146 are connected in a flip-chip manner. However, when the electronic component is a semiconductor chip, it is possible to electrically connect the electronic component to the multilayer wiring substrate 102 by, for example, wire bonding.

Further, in the above-mentioned embodiments, a configuration is shown in which the multilayer wiring substrate 102 includes three wiring layers. However, the multilayer wiring substrate 102 can include any number of the wiring layer insofar as it has two or more layers.

It is apparent that the present invention is not limited to the above embodiment, and may be modified and changed without departing from the scope and spirit of the invention.

What is claimed is:

1. An electronic device comprising:
a multilayer wiring substrate having a first surface and a second surface which oppose to said first surface,
a first insulating film which forms said second surface side of said multilayer wiring substrate,
a plurality of first conductive members formed in said first insulating film to be exposed at said second surface side of said multilayer wiring substrate, and which composes a first wiring layer with said first insulating film,
a second insulating film which forms said first surface side of said multilayer wiring substrate,
a plurality of second conductive members formed in said second insulating film, and which composes a second wiring layer with said second insulating film, and
a first electronic component mounted at said first surface of said multilayer wiring substrate and electrically connected to any of said plurality of second conductive members,
wherein said plurality of second conductive members is respectively connected directly to any of said plurality of first conductive members or connected through a different conductive material, and
said plurality of first conductive members includes a dummy conductive member, and said dummy conductive member is connected directly to any of said plurality of second conductive members or connected through a different conductive material, but do not form current pathways connecting with said connected second conductive member.

2. The electronic device as set forth in claim 1, further comprising a first member formed on said first surface of said multilayer wiring substrate, and electrically connected to said second conductive member through any of said plurality of second conductive members,
wherein said second conductive member electrically connecting said plurality of second conductive members to said first member is connected directly to said dummy conductive member or connected through a different conductive material.

3. The electronic device as set forth in claim 2, wherein said first member is a second electronic component.

4. The electronic device as set forth in claim 1, further comprising a third electronic component mounted on said second surface of said multilayer wiring substrate, and electrically connected to any of said plurality of first conductive members,
wherein said dummy conductive member is formed to be exposed within a region overlapping said third electronic component in said second surface of said multilayer wiring substrate.

5. The electronic device as set forth in claim 4, further comprising a bump connecting said third electronic component to any of said plurality of first conductive members, and an underfill for burying said bump,
wherein said third electronic component is a semiconductor chip, and
said dummy conductive member is formed to be exposed within a region in which said underfill is formed, in said second surface of said multilayer wiring substrate.

6. The electronic device as set forth in claim 5, wherein an exposed surface of said dummy conductive member in said second surface of said multilayer wiring substrate is formed in contact with said underfill.

7. The electronic device as set forth in claim 5, further comprising a bump which is provided to be connected to said dummy conductive member and is not electrically connected to a different member, on said second surface of said multilayer wiring substrate.

8. The electronic device as set forth in claim 1, wherein the exposed surface of said dummy conductive member in said second surface of said multilayer wiring substrate is formed in contact with an insulating material.

9. The electronic device as set forth in claim 1, wherein each of said plurality of second conductive members is a via.

10. The electronic device as set forth in claim 1, wherein each of said plurality of second conductive members is a via formed to have a laminated structure of a copper film and an alloy film of tin and silver, or a laminated structure of a nickel film and an alloy film of tin and silver.

11. A method of manufacturing an electronic device, comprising:
forming a third insulating film over a plurality of third conductive members which is formed over a feed layer, and is respectively electrically connected to said feed layer,
forming a plurality of openings, respectively, that exposes at least one of said plurality of third conductive members to said third insulating film,
forming a plurality of fourth conductive members within said plurality of openings in said third insulating film by an electrolytic plating method of feeding from said feed layer, to form a third wiring layer including said plurality of fourth conductive members and said third insulating film,
mounting a fourth electronic component over said third wiring layer, and electrically connecting any of said plurality of fourth conductive members and said fourth electronic component, and
removing said feed layer,
wherein when said plurality of fourth conductive members is formed, a dummy conductive member provided in order to feed from said feed layer is provided between said plurality of fourth conductive members and said feed layer.

12. The method of manufacturing the electronic device as set forth in claim 11, wherein said step of removing said power supply layer includes exposing said dummy conductive member in a surface from which said feed layer is removed.

13. The method of manufacturing the electronic device as set forth in claim 11, wherein said plurality of fourth conductive members includes said dummy conductive member.

14. The method of manufacturing the electronic device as set forth in claim 11, wherein said electronic device comes in contact with said feed layer, and includes a fourth wiring layer including a fourth insulating film, and a plurality of fifth conductive members formed in said fourth insulating film and respectively electrically connected to said feed layer, and at least said plurality of fifth conductive members includes said dummy conductive member.
